(19) United States
(12) Patent Application Publication
(10) Pub. No.: US 2025/0038147 A1
(43) Pub. Date: Jan. 30, 2025

(54) BONDING DEVICE AND ITS OPERATING METHOD

(71) Applicant: Samsung Display Co., LTD., Yongin-si (KR)

(72) Inventor: Jong Hyup KIM, Yongin-si (KR)

(21) Appl. No.: 18/783,355

(22) Filed: Jul. 24, 2024

(30) Foreign Application Priority Data
Jul. 27, 2023 (KR) 10-2023-0098315

(51) Int. Cl. H01L 23/00

(52) U.S. Cl. CPC H01L 24/75; H01L 24/81; H01L 2224/75252; H01L 2224/75283; H01L 2224/7555; H01L 2224/81203; H01L 2224/8123; H01L 2924/40

(57) ABSTRACT

A bonding device includes a stage supporting a bonding target, a lower transmission member adjacent to the stage in a first direction, an upper transmission member spaced apart from the lower transmission member in the first direction, a chamber between the lower transmission member and the upper transmission member, and partially defining an internal space for accommodating air, a thin film between the chamber and the lower transmission member, defining the internal space together with the chamber, and configured to be deformed according to expansion of the internal space as the air is introduced, and a vertical movement member configured to move the lower transmission member in the first direction, and separable from the lower transmission member.

### CROSS-REFERENCE TO RELATED APPLICATION

The present application claims priority to, and the benefit of, Korean Patent Application No. 10-2023-0098315, filed on Jul. 27, 2023, in the Korean Intellectual Property Office, the entire disclosure of which is incorporated herein by reference.

### BACKGROUND

### 1. Field

The present disclosure generally relates to a bonding device and an operating method thereof.

### 2. Description of the Related Art

With the development of information technologies, the importance of a display device, which is a connection medium between a user and information, increases. Accordingly, display devices, such as a liquid crystal display device, an organic light-emitting display device, and an inorganic light-emitting display device are increasingly used.

In an example, a display panel may be formed by transferring a light-emitting element on a substrate having a thin film transistor formed thereon, and a display device including the formed display panel may be used.

Meanwhile, a process of bonding the light-emitting element may be performed so as to reduce an electrical resistance in an area in which the thin film transistor and the light-emitting element are connected to each other in a process of manufacturing the display panel as described above.

The above information disclosed in this Background section is only for enhancement of understanding of the background of the disclosure, and therefore may contain information that does not form the prior art.

### SUMMARY

Embodiments provide a bonding device capable of applying pressure to a bonding target with improved reliability, and an operating method thereof. For example, in the bonding device and its operating method, substantially uniform pressure can be applied to a bonding target even if a stage is inclined with a plane.

In accordance with an aspect of the present disclosure, there is provided a bonding device including a stage supporting a bonding target, a lower transmission member adjacent to the stage in a first direction, an upper transmission member spaced apart from the lower transmission member in the first direction, a chamber between the lower transmission member and the upper transmission member, and partially defining an internal space for accommodating air, a thin film between the chamber and the lower transmission member, defining the internal space together with the chamber, and configured to be deformed according to expansion of the internal space as the air is introduced, and a vertical movement member configured to move the lower transmission member in the first direction, and separable from the lower transmission member.

The bonding device may further include a first holder between the lower transmission member and the thin film at a first side of the chamber, and a second holder between the lower transmission member and the thin film at a second side of the chamber, wherein a first surface of the first holder, which faces the internal space, has a first inclination with respect to the thin film before the internal space expands, and wherein a second surface of the second holder, which faces the internal space, has a second inclination with respect to the thin film before the internal space expands.

A thickness of the first holder may gradually increase in a direction toward the first side of the chamber, and a thickness of the second holder may gradually increase in a direction toward the second side of the chamber.

The bonding device may further include vertical support members spaced apart from each other in a second direction crossing the first direction with the lower transmission member interposed therebetween, wherein the vertical movement member is configured to move in the first direction along one or more of the vertical support members.

The thin film may be configured to apply pressure to the lower transmission member according to the expansion of the internal space after the lower transmission member is separated from the vertical movement member.

The lower transmission member may be configured to contact the bonding target or the stage without support from the vertical movement member according to the pressure applied by the thin film.

The lower transmission member may be inclined with respect to a plane by an angle at which the stage is inclined with respect to the plane.

The lower transmission member may include lower transmission members spaced apart from each other in a second direction crossing the first direction, and a coupling member connecting the lower transmission members to each other.

The thin film may be configured to apply pressure to the lower transmission members according to the expansion of the internal space after the lower transmission members are separated from the vertical movement member.

The lower transmission members may be inclined with a plane by an angle at which the stage is inclined with respect to the plane.

The bonding device may further include a heat source spaced from the upper transmission member in the first direction, overlapping the stage in the first direction, and configured to irradiate light in a direction opposite to the first direction through the upper transmission member and the lower transmission member.

In accordance with another aspect of the present disclosure, there is provided a method of operating a bonding device including a stage, the method including providing, on the stage, a chamber and a thin film defining an internal space for accommodating air, moving a lower transmission member in a first direction using vertical movement members located between the stage and the thin film, locating a bonding target on an upper surface of the stage that faces the lower transmission member, separating the lower transmission member from the vertical movement member by moving the vertical movement members, transferring pressure to the bonding target through the lower transmission member by expanding the internal space as the air is introduced, and irradiating light through the lower transmission member.

The bonding device may further include an upper transmission member between a heat source for irradiating the light and the chamber, wherein the light is provided to the bonding target through the upper transmission member and the lower transmission member from the heat source.

The method may further include applying pressure to the lower transmission member via the thin film according to expansion of the internal space after the lower transmission member is separated from the vertical movement members.

The lower transmission member may be in contact with the bonding target or the stage without support from the vertical movement member according to the pressure applied by the thin film.

The lower transmission member may include lower transmission members spaced apart from each other in a second direction crossing the first direction, and a coupling member connecting the lower transmission members to each other.

The method may further include applying pressure to each of the lower transmission members via the thin film according to expansion of the internal space after the lower transmission members are separated from the vertical movement members.

### BRIEF DESCRIPTION OF THE DRAWINGS

Embodiments will now be described more fully hereinafter with reference to the accompanying drawings. However, the embodiments may be embodied in different forms, and should not be construed as limited to the aspects set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a front view illustrating a bonding device in accordance with one or more embodiments of the present disclosure.

FIG. 2 is a perspective view illustrating any one of holders shown in FIG. 1.

FIG. 3 is a perspective view illustrating any one of vertical movement members shown in FIG. 1, and a vertical support member corresponding thereto.

FIG. 4 is a front view illustrating an example of the bonding device shown in FIG. 1 in a process of pressurizing a bonding target through a lower transmission member.

FIG. 5 is a view illustrating another example of the bonding device shown in FIG. 1 in the process of pressurizing the bonding target through the lower transmission member.

FIG. 6 is a front view illustrating one or more other embodiments of the bonding device.

FIG. 7 is a flowchart illustrating an operating method of a bonding device in accordance with one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Also, the relative sizes of elements, layers, and regions may be exaggerated for clarity and/or descriptive purposes. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

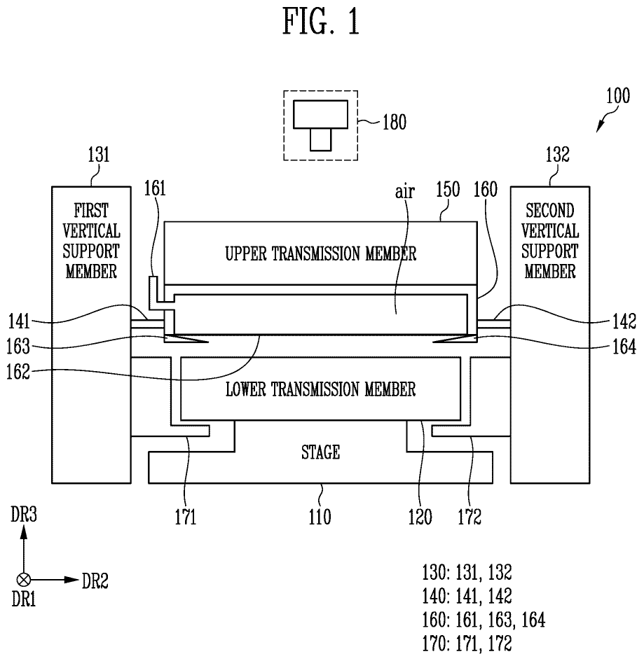

FIG. 1 is a front view illustrating a bonding device in accordance with one or more embodiments of the present disclosure.

Referring to FIG. 1, the bonding device 100 may include a stage 110, a lower transmission member 120, a vertical support member(s) 130, a horizontal support member(s) 140, an upper transmission member 150, a chamber 160, a vertical movement member(s) 170, and a heat source 180.

The stage 110 may have an upper surface extending in a first direction DR1 and in a second direction DR2 crossing the first direction DR1.

The upper surface of the stage 110 may be located in a flat plate shape, but embodiments of the present disclosure are not limited thereto.

The stage 110 may be provided in a three-dimensional shape extending in a third direction DR3 crossing the first direction DR1 and the second direction DR2. For example, the stage 110 may have a rectangular parallelepiped shape or a regular hexahedral shape, but embodiments of the present disclosure are not limited thereto.

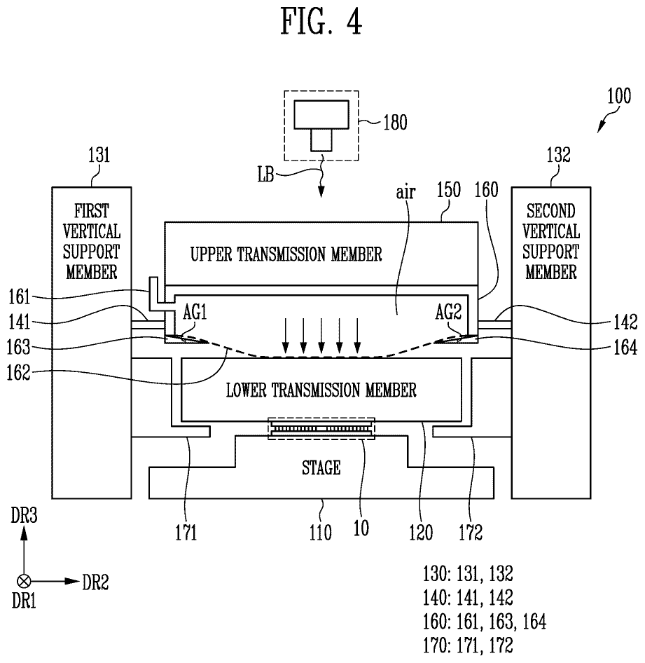

A bonding target 10 (see FIG. 4) may be mounted on the upper surface of the stage 110.

The lower transmission member 120 may have an upper surface and a lower surface, which extend in the first direction DR1 and in the second direction DR2.

The upper surface and the lower surface of the lower transmission member 120 may be located in a flat plate shape, but embodiments of the present disclosure are not limited thereto.

The lower transmission member 120 may be provided in a three-dimensional shape extending in the third direction DR3. For example, the lower transmission member 120 may have a rectangular parallelepiped shape or a regular hexahedral shape, but embodiments of the present disclosure are not limited thereto.

The lower surface of the lower transmission member 120 and the upper surface of the stage 110 may be adjacent to each other in the third direction DR3.

The lower transmission member 120 may be detachable from the vertical movement member(s) 170. According to this configuration, if light is irradiated from the heat source 180, the lower transmission member 120 may be controlled to be in contact with the bonding target or the stage 110 while not being coupled to another component. Accordingly, if the stage 110 is inclined with respect to a plane extending in the first direction DR1 and in the second direction DR2, the lower transmission member 120 may also be inclined by an angle at which the stage 110 is inclined.

The lower transmission member 120 may be formed of a material having light transmissivity (e.g., light transmissivity of light having a wavelength band that is irradiated from the heat source 180). For example, the material having light transmissivity may include quartz, glass, and the like, but the present disclosure is not limited thereto.

The vertical support member(s) 130 may include a first vertical support member 131 and a second vertical support member 132. The first and second vertical support members 131 and 132 may be spaced apart from each other in the second direction DR2. The first and second vertical support members 131 and 132 may be spaced apart from each other with the stage 110, the lower transmission member 120, the chamber 160, and the upper transmission member 150, which are interposed therebetween.

The first vertical support member 131 may extend in the third direction DR3. The first vertical support member 131 may support a first horizontal support member 141 and a first vertical movement member 171. The first vertical support member 131 may have various shapes.

The second vertical support member 132 may extend in the third direction DR3. The second vertical support member 132 may support a second horizontal support member 142 and a second vertical movement member 172. The second vertical support member 132 may have various shapes.

The horizontal support member(s) 140 may include the first horizontal support member 141 and the second horizontal support member 142.

The first horizontal support member 141 may extend in the second direction DR2. The first horizontal support member 141 may be coupled to the first vertical support member 131, and may support the chamber 160. The first horizontal support member 141 may have various shapes.

The second horizontal support member 142 may extend in the second direction DR2. The second horizontal support member 142 may be coupled to the second vertical support member 132, and may support the chamber 160. The second horizontal support member 142 may have various shapes.

The upper transmission member 150 may have an upper surface and a lower surface, which extend in the first direction DR1 and the second direction DR2.

The upper surface and the lower surface of the upper transmission member 150 may be a flat plate shape, but embodiments of the present disclosure are not limited thereto.

The upper transmission member 150 may be provided in a three-dimensional shape extending in the third direction DR3. For example, the upper transmission member 150 may have a rectangular parallelepiped shape or a regular hexahedral shape, but embodiments of the present disclosure are not limited thereto.

The lower surface of the upper transmission member 150 and the chamber 160 may be adjacent to each other in the third direction DR3.

The upper transmission member 150 may be formed of a material having light transmissivity (e.g., light transmissivity of light having a wavelength band that is irradiated from the heat source 180). For example, the material having light transmissivity may include quartz, glass, and the like, but the present disclosure is not limited thereto.

The chamber 160 may include an air inlet 161, a first holder 163, and a second holder 164.

The chamber 160 is configured to apply pressure to the bonding target 10 located on the stage 110. The chamber 160 may define an internal space together with a thin film 162, and the internal space may accommodate a gas (e.g., air) injected through the air inlet 161. The internal space may expand due to the gas injected into the internal space of the chamber 160, and accordingly, the thin film 162 may be deformed. The gas injected into the internal space of the chamber 160 may include, for example, an inert gas having low reactivity, but embodiments of the present disclosure are not limited thereto. As the gas is injected into the internal space of the chamber 160, air pressure of the internal space of the chamber 160 may become higher than atmospheric pressure. In some embodiments, the gas injected into the chamber 160 may be discharged through an air outlet provided in the chamber 160.

In one or more embodiments, the air inlet 161 may include a valve. As the valve is opened or closed, the gas may be injected into the chamber 160, or the injection of the gas may be blocked.

The thin film 162 along with the chamber 160 may define the internal space of the chamber 160. The thin film 162 may be understood as a component included in the chamber 160. The thin film 162 may be understood as a lower surface of the chamber 160.

The thin film 162 may be configured to apply pressure to the bonding target 10 located on the stage 110. The thin film 162 may be formed of a material having elasticity. For example, the thin film 162 may include a rubber material, and/or a plastic material (e.g., polyimide) having flexibility, but embodiments of the present disclosure are not limited thereto. The thin film 162 may be deformed due to the elasticity thereof, and therefore, the internal space defined by the chamber 160 and the thin film 162 may expand if the gas is introduced through the air inlet 161. When the thin film 162 expands, the thin film 162 may be in surface contact with the upper surface of the lower transmission member 120. Pressure may be applied to a surface contact area of the lower transmission member 120 by the expanding thin film 162. The pressure may be transferred to the bonding target 10 through the lower transmission member 120.

The first holder 163 may be coupled to one side of the chamber 160, which faces the first vertical support member 131. The second holder 164 may be coupled to the other side of the chamber 160, which faces the second vertical support member 132. The first holder 163 and the second holder 164 may be spaced apart from each other in the second direction DR2 with the thin film 162 interposed therebetween.

The first holder 163 may be located between the lower transmission member 120 and the thin film 162 at the one side of the chamber 160. The second holder 164 may be located between the lower transmission member 120 and the thin film 162 at the other side of the chamber 160. Accordingly, the first holder 163 and the second holder 164 may be adhered closely to the thin film 162 if the thin film 162 expands.

A portion of the chamber 160 that overlaps with the lower transmission member 120 and the upper transmission member 150, and the thin film 162, may be formed of a material having light transmissivity (e.g., light transmissivity of light having a wavelength band that is irradiated from the heat source 180). For example, the material having light transmissivity may include quartz, glass, and the like, but the present disclosure is not limited thereto. Accordingly, at least a portion of light irradiated from the heat source 180 may be provided to the bonding target 10 while passing through the upper transmission member 150, the thin film 162, and the lower transmission member 120.

The vertical movement member(s) 170 may include the first vertical movement member 171 and the second vertical movement member 172.

The vertical movement member(s) 170 may be configured to move the lower transmission member 120. For example, the vertical movement member(s) 170 may move (e.g., lift and drive) the lower transmission member 120 in the third direction DR3 and in the direction that is opposite to the third direction DR3. The vertical movement member(s) 170 may include a motor to move the lower transmission member 120.

The first vertical movement member 171 may be coupled to the first vertical support member 131, and may have various shapes. The second vertical movement member 172 may be coupled to the second vertical support member 132, and may have various shapes.

The first vertical movement member 171 and the second vertical movement member 172 may be spaced apart from each other in the second direction DR2 with the lower transmission member 120 and the stage 110, which are interposed therebetween.

The heat source 180 may irradiate light. The light irradiated from the heat source 180 may be incident into the chamber 160 through an upper surface of the chamber 160 while passing through the upper transmission member 150. Also, the light irradiated from the heat source 180 may pass through the thin film 162, and may be incident onto the bonding target 10 while passing through the lower transmission member 120. Accordingly, heat may be applied to the bonding target 10 in a bonding process. In some embodiments, the heat source 180 may irradiate infrared light having a wavelength band that is longer than a wavelength band of visible light, but embodiments of the present disclosure are not limited thereto.

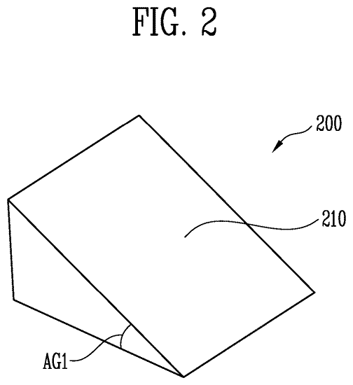

FIG. 2 is a perspective view illustrating any one of the holders shown in FIG. 1. A holder 200 shown in FIG. 2 may be provided as at least one of the first holder 163 and/or the second holder 164, which are shown in FIG. 1.

Referring to FIGS. 1 and 2, the holder 200 may have an inclined surface 210. The inclined surface 210 may have an inclination of a first angle AG1 from a bottom surface of the holder 200 (or a plane direction defined by the first and second directions DR1 and DR2).

The holder 200 may have various shapes including the inclined surface 210. However, the shape of the holder 200 is not limited to the shape shown in FIG. 2.

The inclined surface 210 may adhere relatively closely to the thin film 162 if the thin film 162 expands due to the air injected into the chamber 160.

When the thin film 162 expands, inclination angles of inclined surfaces of the thin film 162 may not reach a corresponding angle or more. For example, the inclination angle of the one inclined surface of the thin film 162 may be equal (or substantially equal) to the first angle AG1 as the inclination angle of the holder 200. Also, the inclination angle of the other inclined surface of the thin film 162 may be equal (or substantially equal) to the first angle AG1 as the inclination angle of the holder 200.

When the holder 200 does not exist in the bonding device 100, the thin film 162 expanding due to the air injected into the internal space of the chamber 160 may be in contact with the lower transmission member 120 throughout a larger area. As the contact surface becomes larger, pressure per unit area, which is suitable for the bonding process, may increase. For example, a higher pressure may be suitable to be applied to the lower transmission member 120 by the thin film 162. To apply the higher pressure, the thin film 162 may further expand unintentionally due to injection of a corresponding amount of air or more. Due to the expansion of the thin film 162, the thin film 162 may be damaged.

On the other hand, the holder 200 is provided at each of the one side and the other side of the chamber 160, so that the thin film 162 can be in contact with an intended area of the lower transmission member 120 if the internal space of the chamber 160 expands. Accordingly, a suitable amount of air can be injected into the chamber 160 so as to apply pressure suitable for the bonding process. In addition, unintended expansion of the thin film 162 can be reduced or prevented.

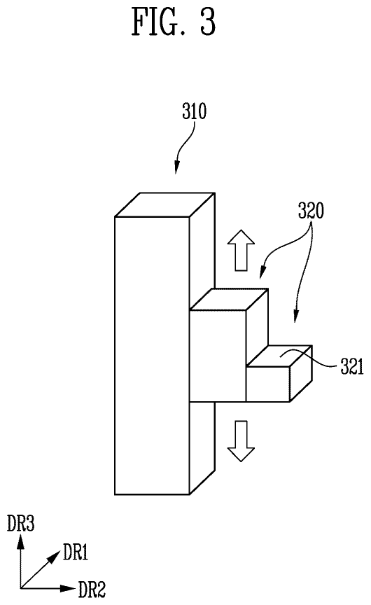

FIG. 3 is a perspective view illustrating any one of the vertical movement members shown in FIG. 1 and a vertical support member corresponding thereto. The first vertical support member 131 and the first vertical movement member 171, which are shown in FIG. 1, may be provided as a vertical support member 310 and a vertical movement member 320, which are shown in FIG. 3. In addition, the second vertical support member 132 and the second vertical movement member 172, which are shown in FIG. 1, may be provided as the vertical support member 310 and the vertical movement member 320, which are shown in FIG. 3.

Referring to FIGS. 1 and 3, the vertical movement member 320 may be coupled to the vertical support member 310 in the second direction DR2.

The vertical movement member 320 may be configured to move the lower transmission member 120. For example, an upper surface 321 of the vertical movement member 320 may support a portion of the lower surface of the lower transmission member 120. In one or more embodiments, the vertical movement member 320 may include a motor. The vertical movement member 320 may move (e.g., lift and drive) the lower transmission member 120 in the third direction DR3 and the opposite direction of the third direction DR3.

The upper surface 321 of the vertical movement member 320 may have various shapes. The shape of the upper surface is not limited to the shape shown in FIG. 3.

FIG. 4 is a front view illustrating an example of the bonding device shown in FIG. 1 in a process of pressurizing the bonding target through the lower transmission member.

Referring to FIGS. 1 and 4, the first vertical movement member 171 and the second vertical movement member 172 may move the lower transmission member 120 in the third direction DR3. The lower transmission member 120 may be spaced apart from the upper surface of the stage 110. Accordingly, the bonding target 10 may be located between the lower transmission member 120 and the upper surface of the stage 110.

After that, as the valve of the air inlet 161 is opened, the air may be injected into the internal space of the chamber 160. As the air is injected into the chamber 160, the air pressure inside the chamber 160 may become higher the atmospheric pressure. Accordingly, the thin film 162 may expand.

When the thin film 162 expands, the inclination angles of one and the other inclined surfaces of the thin film 162 may not exceed a corresponding reference angle. For example, an inclination angle that one side of the thin film 162 forms with respect to a plane may be substantially equal to the first angle AG1 as the inclination angle of the first holder 163, and an inclination angle that the other side of the thin film 162 forms with respect to the plane may be substantially equal to the second angle AG2 as the inclination angle of the second holder 164.

The expanding thin film 162 may be substantially uniformly in contact with a portion of the upper surface of the lower transmission member 120. The expanding thin film 162 may apply substantially uniform pressure to the lower transmission member 120 in the surface contact area (see arrows shown in FIG. 4). Accordingly, the lower transmission member 120 may apply substantially uniform pressure to the bonding target 10.

After that, the heat source 180 may irradiate light LB. The light LB irradiated from the heat source 180 may reach the bonding target 10 while passing through the upper transmission member 150, the chamber 160, and the lower transmission member 120. The light LB may provide heat to the bonding target 10.

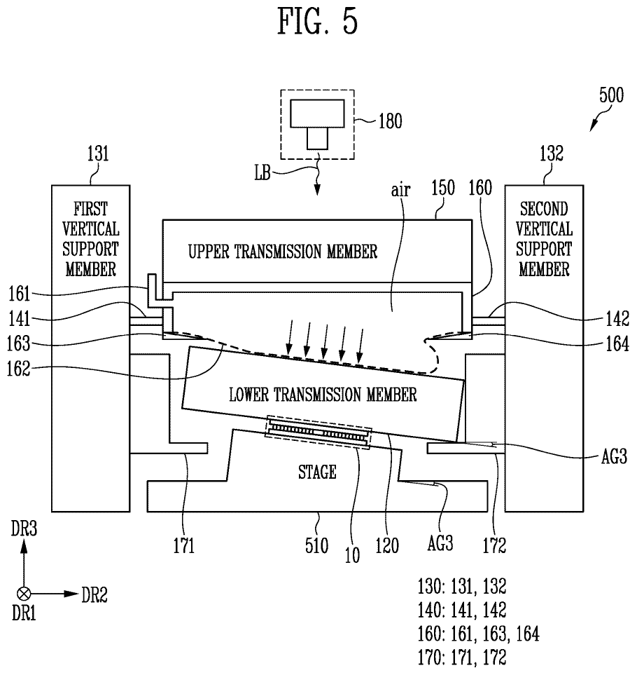

FIG. 5 is a view illustrating another example of the bonding device shown in FIG. 1 in the process of pressurizing the bonding target through the lower transmission member.

Referring to FIG. 5, an upper surface of a stage 510 may not be parallel to a plane extending in the first direction DR1 and the second direction DR2. For example, as shown in FIG. 5, the upper surface of the stage 510 may be inclined by a third angle AG3 with respect to a surface (e.g., a ground surface) according to abrasion, corrosion or the like in a process.

In accordance with one or more embodiments of the present disclosure, like the stage 510, the lower transmission member 120 may be inclined by the third angle AG3 with respect to the plane.

When the lower transmission member 120 is fixed to a component like the vertical movement member(s) 170, the lower transmission member 120 may maintain a state in which the lower transmission member 120 is parallel to the plane regardless that the upper surface of the stage 510 is inclined with respect to the plane.

In accordance with one or more embodiments of the present disclosure, if the internal space of the chamber 160 expands, the lower transmission member 120 is not fixed to the vertical movement member(s) 170, and accordingly, the lower transmission member 120 may be inclined by the third angle AG3 with respect to the plane, like the stage 510.

As the air is injected into the chamber 160, the air pressure inside the chamber 160 may become higher the atmospheric pressure. Accordingly, the thin film 162 may expand.

The expanding thin film 162 may be substantially uniformly in contact with a portion of the upper surface of the lower transmission member 120. The expanding thin film 162 may apply substantially uniform pressure to the lower transmission member 120 in the surface contact area (see arrows shown in FIG. 5). Accordingly, the lower transmission member 120 may apply substantially uniform pressure to the bonding target 10.

After that, the heat source 180 may irradiate light LB. The light LB irradiated from the heat source 180 may reach the bonding target 10 while passing through the upper transmission member 150, the chamber 160, and the lower transmission member 120. The light LB may provide heat to the bonding target 10.

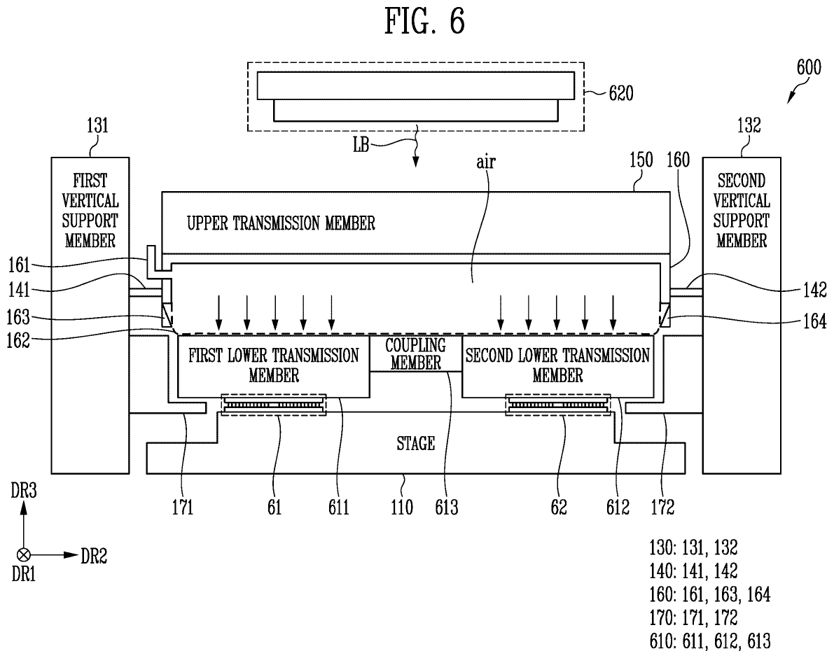

FIG. 6 is a front view illustrating one or more other embodiments of the bonding device.

Referring to FIG. 6, a bonding device 600 may include a stage 110, a lower transmission member(s) 610, a thin film 162, an upper transmission member 150, and a heat source 620. Hereinafter, descriptions of portions overlapping with those shown in FIG. 1 will be omitted.

The lower transmission member(s) 610 may include a plurality of lower transmission members. For example, as shown in FIG. 6, the lower transmission member(s) 610 may include a first lower transmission member 611, a second lower transmission member 612, and a coupling member 613, but the present disclosure is not limited thereto.

The first lower transmission member 611 and the second lower transmission member 612 may be connected to each other by the coupling member 613. The lower transmission member(s) 610 may be moved in the third direction DR3 or in the direction that is opposite to the third direction DR3 by a first vertical movement member 171 and a second vertical movement member 172.

As air is injected into an internal space of a chamber 160, air pressure inside the chamber 160 may become higher than atmospheric pressure. Accordingly, the thin film 162 may expand.

The expanding thin film 162 may be substantially uniformly in contact with an upper surface of the first lower transmission member 611. Also, the expanding thin film 162 may be substantially uniformly in contact with a portion of an upper surface of the second lower transmission member 612.

The expanding thin film 162 may apply substantially uniform pressure to an area in surface contact with the first lower transmission member 611 (see arrows shown in FIG. 6). Accordingly, the first lower transmission member 611 may apply substantially uniform pressure to a bonding target 61. Also, the expanding thin film 162 may apply substantially uniform pressure to an area in surface contact with the second lower transmission member 612. Accordingly, the second lower transmission member 612 may apply substantially uniform pressure to a bonding target 62.

Pressure may apply may be applied to a plurality of bonding targets 61 and 62 through a plurality of lower transmission members 611 and 612.

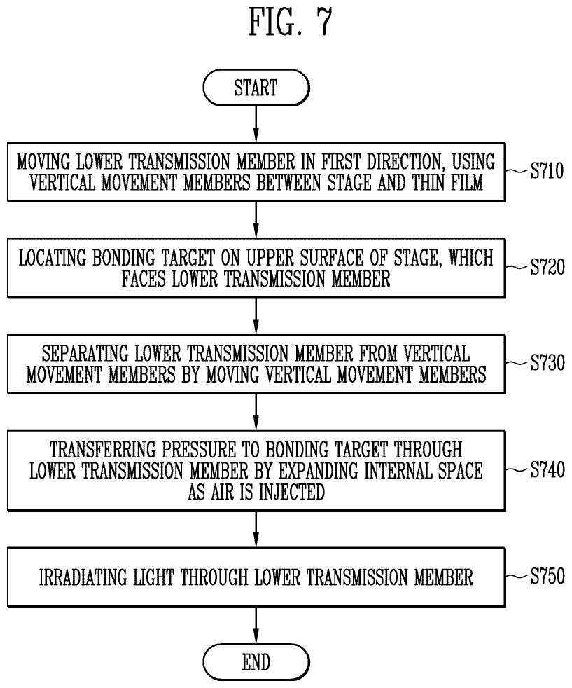

FIG. 7 is a flowchart illustrating an operating method of a bonding device in accordance with one or more embodiments of the present disclosure.

Referring to FIGS. 4 and 7, in S710, the lower transmission member 120 may be moved using the vertical movement members 171 and 172 between the stage 110 and the thin film 162.

In S720, the bonding target 10 may be located on the upper surface of the stage 110, which faces the lower transmission member 120.

In S730, the lower transmission member 120 may be separated from the vertical movement members 171 and 172 by moving the vertical movement members 171 and 172.

In S740, pressure may be transferred to the bonding target 10 through the lower transmission member 120 by expanding the internal space of the chamber 160 as the air is introduced.

In S750, the light LB may be irradiated through the lower transmission member 120.

Before the internal space of the chamber 160 expands as the air is introduced, the vertical movement members 171 and 172 can be separated from the lower transmission member 120 by moving the vertical movement members 171 and 172. Accordingly, the lower transmission member 120 can apply substantially uniform pressure to the bonding target 10 based on the expansion of the internal space of the chamber 160. Thus, the pressure can be applied to the bonding target with improved reliability.

In accordance with the present disclosure, there can be provided a bonding device capable of applying pressure to a bonding target with improved reliability, and an operating method thereof.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, aspects described in connection with a particular embodiment may be used singly or in combination with aspects described in connection with other embodiments unless otherwise specifically indicated. Accordingly, it will be understood by those of skill in the art that various changes in form and details may be made without departing from the spirit and scope of the present disclosure as set forth in the following claims, with functional equivalents thereof to be included therein.

What is claimed is:

1. A bonding device comprising:
a stage supporting a bonding target;
a lower transmission member adjacent to the stage in a first direction;
an upper transmission member spaced apart from the lower transmission member in the first direction;
a chamber between the lower transmission member and the upper transmission member, and partially defining an internal space for accommodating air;
a thin film between the chamber and the lower transmission member, defining the internal space together with the chamber, and configured to be deformed according to expansion of the internal space as the air is introduced; and
a vertical movement member configured to move the lower transmission member in the first direction, and separable from the lower transmission member.

2. The bonding device of claim 1, further comprising:
a first holder between the lower transmission member and the thin film at a first side of the chamber; and
a second holder between the lower transmission member and the thin film at a second side of the chamber,
wherein a first surface of the first holder, which faces the internal space, has a first inclination with respect to the thin film before the internal space expands, and
wherein a second surface of the second holder, which faces the internal space, has a second inclination with respect to the thin film before the internal space expands.

3. The bonding device of claim 2, wherein a thickness of the first holder gradually increases in a direction toward the first side of the chamber, and
wherein a thickness of the second holder gradually increases in a direction toward the second side of the chamber.

4. The bonding device of claim 1, further comprising vertical support members spaced apart from each other in a second direction crossing the first direction with the lower transmission member interposed therebetween,
wherein the vertical movement member is configured to move in the first direction along one or more of the vertical support members.

5. The bonding device of claim 1, wherein the thin film is configured to apply pressure to the lower transmission member according to the expansion of the internal space after the lower transmission member is separated from the vertical movement member.

6. The bonding device of claim 5, wherein the lower transmission member is configured to contact the bonding target or the stage without support from the vertical movement member according to the pressure applied by the thin film.

7. The bonding device of claim 6, wherein the lower transmission member is inclined with respect to a plane by an angle at which the stage is inclined with respect to the plane.

8. The bonding device of claim 1, wherein the lower transmission member comprises:
lower transmission members spaced apart from each other in a second direction crossing the first direction; and
a coupling member connecting the lower transmission members to each other.

9. The bonding device of claim 8, wherein the thin film is configured to apply pressure to the lower transmission members according to the expansion of the internal space after the lower transmission members are separated from the vertical movement member.

10. The bonding device of claim 9, wherein the lower transmission members are inclined with a plane by an angle at which the stage is inclined with respect to the plane.

11. The bonding device of claim 1, further comprising a heat source spaced from the upper transmission member in the first direction, overlapping the stage in the first direction, and configured to irradiate light in a direction opposite to the first direction through the upper transmission member and the lower transmission member.

12. A method of operating a bonding device comprising a stage, the method comprising:
providing, on the stage, a chamber and a thin film defining an internal space for accommodating air;
moving a lower transmission member in a first direction using vertical movement members located between the stage and the thin film;
locating a bonding target on an upper surface of the stage that faces the lower transmission member;
separating the lower transmission member from the vertical movement member by moving the vertical movement members;
transferring pressure to the bonding target through the lower transmission member by expanding the internal space as the air is introduced; and
irradiating light through the lower transmission member.

13. The method of claim 12, wherein the bonding device further comprises an upper transmission member between a heat source for irradiating the light and the chamber, and
wherein the light is provided to the bonding target through the upper transmission member and the lower transmission member from the heat source.

14. The method of claim 12, further comprising applying pressure to the lower transmission member via the thin film according to expansion of the internal space after the lower transmission member is separated from the vertical movement members.

15. The method of claim 14, wherein the lower transmission member is in contact with the bonding target or the stage without support from the vertical movement member according to the pressure applied by the thin film.

16. The method of claim 12, wherein the lower transmission member comprises:
lower transmission members spaced apart from each other in a second direction crossing the first direction; and
a coupling member connecting the lower transmission members to each other.

17. The method of claim 16, further comprising applying pressure to each of the lower transmission members via the thin film according to expansion of the internal space after the lower transmission members are separated from the vertical movement members.
